(19) United States
(12) Patent Application Publication
(10) Pub. No.: US 2022/0066310 A1
(43) Pub. Date: Mar. 3, 2022

(54) BLANKMASK WITH BACKSIDE CONDUCTIVE LAYER, AND PHOTOMASK MANUFACTURED WITH THE SAME

(71) Applicant: S&S TECH Co., Ltd., Daegu-si (KR)

(72) Inventors: Gyeong-Won SEO, Daegu-si (KR); Gil-Woo KONG, Daegu-si (KR); Chul-Kyu YANG, Daegu-si (KR)

(73) Assignee: S&S TECH Co., Ltd., Daegu-si (KR)

(21) Appl. No.: 16/951,169

(22) Filed: Nov. 18, 2020

(30) Foreign Application Priority Data
Sep. 2, 2020 (KR) 10-2020-0111761

(51) Int. Cl. G03F 1/24; H01L 21/033

(52) U.S. Cl. CPC G03F 1/24; H01L 21/0332; H01L 21/0337

(57) ABSTRACT

A blankmask includes a conductive layer attached to a backside of a substrate, and the conductive layer includes a first layer, a second layer, and a third layer that are sequentially stacked on the backside of the substrate. The first layer and the third layer are made of a material that contains chromium (Cr) and oxygen (O), and the second layer is made of a material that does not contain the oxygen (O) but contains the chromium (Cr). There is provided the blankmask with the conductive layer having characteristics of low sheet resistance, high adhesion to the substrate, and low stress applied to the substrate.

### CROSS-REFERENCE TO RELATED APPLICATION

This application is based on and claims priority under 35 U. S. C. § 119 to Korean Patent Application No. 10-2020-0111761, filed on Sep. 2, 2020, the disclosure of which is herein incorporated by reference in its entirety.

### BACKGROUND

### 1. Field

The disclosure relates to a blankmask and a photomask, and more particularly, to a blankmask with a conductive layer on a backside of a substrate and a photomask manufactured with the same.

### 2. Discussion of Related Art

A blankmask has a structure in which various kinds of thin films are stacked on a substrate. Any kind of blankmask, for example, a reflective blankmask for extreme ultraviolet (EUV) has a conductive layer on a backside of a substrate. FIG. 1 is a side cross-sectional view of a conventional blankmask.

The blankmask includes a substrate 110, various kinds of thin films (not illustrated) such as a reflection film and an absorbing film formed on a front side of the substrate 110, and a conductive layer 120 formed on the backside of the substrate 110. The conductive layer 120 serves to improve adhesion between an electronic-chuck and the blankmask, and prevent particles from being generated due to friction between the electronic-chuck and the blankmask. The conductive layer 120 is typically made of a chromium (Cr)-based material.

The conductive layer 120 needs to have characteristics such as low sheet resistance, high adhesion to the substrate 110, and low stress applied to the substrate 110. When the sheet resistance is high, there is a risk of dielectric breakdown because it is necessary to apply a high voltage to obtain high adhesion to the electronic-chuck. When the adhesion to the conductive layer 120 is low, there may be a problem in that alignment deteriorates as the blankmask slides during chucking. In addition, the conductive layer 120 made of the Cr-based material applies a tensile stress to the backside of the substrate 110, thereby generating compressive stress on the front side of the substrate 110. The compressive stress applied to the substrate 110 increases a flatness value of the substrate 110, causing an increase in an overlay.

### SUMMARY

The disclosure is to provide a blankmask with a conductive layer having characteristics of low sheet resistance, high adhesion to a substrate, and low stress applied to the substrate.

According to an aspect of the disclosure, a blankmask includes a first layer, a second layer, and a third layer in which a conductive layer attached to a backside of a substrate is sequentially stacked on the backside thereof, in which the first layer and the third layer are made of a material that contains chromium (Cr) and oxygen (O), and the second layer is made of a material that does not contain the oxygen (O) but contains the chromium (Cr),

At least one of the first layer, the second layer, and the third layer may be made of a material that further contains nitrogen (N).

At least one of the first layer, the second layer, and the third layer may be made of a material that further contains carbon (C).

The first layer and the third layer may be made of CrCON, and the second layer may be made of CrCN.

The first layer may be made of 20 to 70 at % of chromium (Cr). 30 to 80 at % of oxygen (O), and 0 to 50% of a sum total of nitrogen and carbon, the second layer may be made of 40 to 100% of chromium (Cr) and 0 to 60% of a sum total of nitrogen and carbon, and the third layer may be made of 20 to 70 at % of chromium (Cr), 30 to 80 at % of oxygen (O), and 0 to 50% of a sum total of nitrogen and carbon.

At least one of the first layer, the second layer, and the third layer may be made of a material that further contains at least one element selected from the group consisting of hydrogen (H) boron (B), aluminum (Al) silver (Ag), cobalt (Co) copper (Cu), iron (Fe), hafnium (Hf), indium (In), molybdenum (Mo), nickel (Ni), niobium (Nb), silicon (Si), tantalum (Ta), titanium(Ti), zinc (Zn), and zirconium (Zr).

A content of the element may be 1.5 at % or less.

The first layer may have a surface roughness of 0.5 nm RMS or less.

The first layer may have a thickness of 10 to 100 nm.

The second layer may have a sheet resistance of 100 Ω/□ or less.

The second layer may have a thickness of 10 to 60 nm.

The third layer may have a surface roughness of 0.5 nm RMS or less.

The third layer may have a thickness of 1 to 30 nm.

According to the disclosure, a photomask manufactured with the blankmask configured as described above is provided.

According to the disclosure, there is provided the blankmask with the conductive layer having the characteristics of the logs sheet resistance, the high adhesion to the substrate, and the logs stress applied to the substrate.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a side cross-sectional view of a conventional blankmask.

FIG. 2 is a side cross-sectional view of a blankmask according to the disclosure.

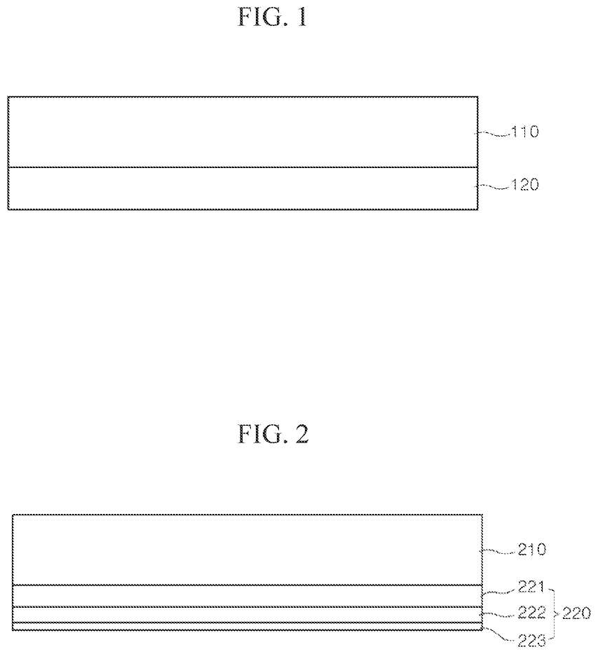

### DETAILED DESCRIPTION

Hereinafter, preferred embodiments of the disclosure will be described in more detail with reference to the drawings.

FIG. 2 is a side cross-sectional view of a blankmask according to the disclosure. The disclosure illustrates a reflective blankmask for extreme ultraviolet (EUV). However, the disclosure is not limited thereto, and applies to all kinds of blankmasks with a conductive layer.

The blankmask includes a substrate 210, various kinds of thin films (not illustrated) such as a reflection film and an absorbing film formed on a front side of the substrate 210, and a conductive layer 220 formed on the backside of the substrate 210.

The substrate 210 is a class substrate for a reflective blankmask using EUV exposure light, and is configured as a low thermal expansion material (LTEM) substrate having a low coefficient of thermal expansion within the range of 0±1.0×10⁻⁷/° C. and preferably 0±0.3×10⁻⁷/° C. in order to prevent deformation of a pattern due to heat and stress during exposure. As the material of the substrate 210, SiO₂-TiO₂-based glass, multi-component glass ceramic, or the like may be used.

The substrate 210 needs to have high flatness in order to increase accuracy of reflected light during exposure. The flatness is represented by a total indicated reading (TIR) value, and it is preferable that the substrate 210 has a low TIR value. The flatness of the substrate 210 is 100 nm or less and preferably 50 nm or less in an area of 132 mm² or an area of 142 mm².

Various kinds of thin films are formed on a front side (upper surface in FIG. 2) of the substrate 210. In the case of the reflective blankmask for EUV, thin films such as a reflection film and an absorbing film are formed.

The conductive layer 220 is formed on the backside (Iowa surface in FIG. 2) of the substrate 210. The conductive layer 220 is configured to include three layers, that is, a first layer 221, a second layer 222, and a third layer 223. The conductive layer 220 of the disclosure may include an additional layer in addition to the three layers 221, 222, and 223. In addition, each of the layers 221, 222, and 223 may be configured to include a plurality of sub-layers, and in this case, the sub-layers may be configured to have different compositions and/or composition ratios. In addition, each of the layers 221, 222, 223 may be formed in a continuous film whose composition and/or composition ratio continuously changes.

The conductive layer 220 has a thickness of 21 nm to 190 nm. In addition, the conductive layer 220 is configured to have a sheet resistance of 100 Ω/□ or less and a surface roughness of 0.5 nm RMS or less. In addition, the conductive layer 220 is configured to have a flatness of 150 nm or less in a form having compressive stress.

The first layer 221 is a layer in contact with the substrate 210 and is made of a material containing chromium (Cr) and oxygen (O). The first layer 221 may further contain nitrogen (N). and may further contain carbon (C). Preferably, the first layer 221 is made of CrCON.

The oxygen (O) contained in the first layer 221 serves to increase adhesion between the substrate 210 and the first layer 221, and also increases the compressive stress of the first layer 221 to reduce tensile stress which is caused by the Cr material. In addition, the carbon (C) contained in the first layer 221 further reduces the tensile stress of the first layer 221 and relatively reduces the sheet resistance, thereby serving to implement smooth adhesion to the electronic-chuck.

The nitrogen (N) contained in the first layer 221 serves to reduce the surface roughness of the first layer 221 by securing amorphousness of the first layer 221. That is, the nitrogen (N) is contained, and as a result, the first layer 221 becomes amorphous and the surface smoothness is excellent. The first layer 221 is controlled to have a surface roughness of 0.5 nm RMS or less. When the surface roughness is 0.5 nm RMS or more, the adhesion between the first layer 221 and the substrate 210 may be reduced. Accordingly, by controlling the surface roughness to be 0.5 nm RMS or less, the adhesion between the first layer 221 and the substrate 210 may be enhanced. As a result, peeling of the first layer 221 is prevented and generation of particles is prevented. The surface roughness of the first layer 221 is preferably 0.4 nm RMS or less, and most preferably 0.3 nm RMS or less.

It is preferable that the first layer 221 has a thickness of 10 to 100 nm. When the thickness of the first layer 221 is 10 nm or less, it is difficult to secure sufficient adhesion and sufficient compressive stress. When the thickness of the first layer 221 is 100 nm or more, the time required to form the first layer 221 increases and the thickness of the first layer 221 increases more than necessary without increasing additional compressive stress or adhesion, so there is an increased fear of peeling. The thickness of the first layer 221 is more preferably 20 to 90 nm, and most preferably 30 to 80 nm.

The second layer 222 is a layer formed on the first layer 221, and is made of a material that does not contain oxygen (O) but contains chromium (Cr). The first layer 221 may further contain nitrogen (N), and may further contain carbon (C). Preferably, the first layer 221 is made of CrCN.

The second layer 222 does not contain oxygen (O) and thus serves to lower the entire resistance of the conductive layer 220. It is preferable that the second layer 222 has a sheet resistance of 100 Ω/□ or less. The carbon (C) contained in the second layer 222 relatively reduces the sheet resistance, and as a result, serves to implement the smooth adhesion to the electronic-chuck.

The second layer 22 has a thickness of 10 to 60 nm. When the thickness of the second layer 222 is 10 nm or less, the total resistance value of the conductive layer 220 cannot be sufficiently reduced. When the thickness of the second layer 222 is 60 nm or more, an additional resistance reduction effect is very small, and the time required to form the second layer 222 increases and the thickness of the second layer 222 increases more than necessary, so there is an increased fear of peeling. The thickness of the second layer 222 is more preferably 20 to 50 mm and most preferably 25 to 45 nm.

The third layer 223 is a layer formed on the second layer 222 and is made of a material containing chromium (Cr) and oxygen (O). The third layer 223 may further contain nitrogen (N), and may further contain carbon (C). Preferably, the third layer 223 is made of CrCON.

The oxygen (O) contained in the third layer 223 serves to increase the adhesion between the electronic-chuck and the third layer 223. The carbon (C) contained in the third layer 223 relatively reduces the sheet resistance, and as a result, serves to implement the smooth adhesion to the electronic-chuck.

The nitrogen (N) contained in the third layer 223 serves to reduce the surface roughness of the third layer 223 by securing amorphousness of the third layer 223. That is, the nitrogen (N) is contained, and as a result, the third layer 223 becomes amorphous and the surface smoothness is excellent. The third layer 223 is controlled to have a surface roughness of 0.5 nm RMS or less. When the surface roughness is 0.5 nm RMS or more, it is difficult to secure the adhesion between the third layer 223 and the electronic-chuck. The surface roughness is controlled to be 0.5 nm RMS or less, and as a result, it is possible to enhance the adhesion between the third layer 223 and the electronic-chuck. Accordingly, the generation of particles due to friction between the electronic-chuck and the conductive layer 220 may be suppressed while the substrate 210 on which the conductive layer 220 is formed is adsorbed by the electronic-chuck. The surface roughness of the third layer 223 is preferably 0.4 nm RMS or less, and most preferably 0.3 nm RMS or less.

The third layer 223 has a thickness of 1 to 30 nm. When the thickness of the third layer 223 is 1 nm or less, it is difficult to secure the adhesion to the electronic-chuck. When the thickness of the third layer 223 is 30 nm or more, there is no effect of securing additional adhesion and the time required to form the third layer 223 increases. The thickness of the third layer 223 is more preferably 3 to 20 nm, and most preferably 5 to 15 nm.

At least one of the first layer, the second layer, and the third layer may further contain at least one element selected from the group consisting of hydrogen (H), boron (B), aluminum (Al), silver (Ag), cobalt (Co), copper (Cu), iron (Fe), hafnium (Hf), indium (In), molybdenum (Mo), nickel (Ni), niobium (Nb), silicon (Si), tantalum (Ta), titanium (Ti), zinc (Zn), and zirconium (Zr), By setting the content of these elements to 15 at % or less, a crystal structure of the first to third layers 221 to 223 may be amorphized and the surface thereof may be further smoothed.

Meanwhile, the entire conductive layer 220 may be formed to have a form of a continuous film. In this case, the conductive layer 220 is configured so that the content of oxygen (O) decreases and the content of nitrogen (N) increases from a point adjacent to the substrate 210 to an intermediate point in a direction away from the substrate 210, and is configured so that the content of oxygen (O) increases and the content of nitrogen (N) decreases from the intermediate point to the opposite side of the substrate 210. As a result, the second layer 222 made of chromium or a chromium compound in which oxygen (O) is not contained is configured in the intermediate region of the conductive layer 220 in a thickness direction.

Specifically, the composition ratio of each conductive layer is preferably configured as follows. The first layer 221 of the conductive layer 220 may be made of 20 to 70 at % of chromium (Cr), 30 to 80 at % of oxygen (O), and 0 to 50% of a sum total of nitrogen and carbon, the second layer may be made of 40 to 100% of chromium (Cr) and 0 to 60% of a sum total of nitrogen and carbon, and the third layer may be made of 20 to 70 at % of chromium (Cr), 30 to 80 at % of oxygen (O), and 0 to 50% of a sum total of nitrogen and carbon.

### EXAMPLE 1

A conductive layer having a three-layer structure mainly made of Cr was formed on a backside of a SiO₂-TiO₂-based transparent substrate using DC magnetron reactive sputtering equipment. All of the first to third layers of the conductive layer were formed using a Cr target.

The first layer was formed of a CrCON film having a thickness of 41 nm by injecting Ar:N₂:CO₂=6 sccm:10 sccm:6 sccm as a process gas and using a process power of 1.4 kW. The second layer was formed of a CrCN film having a thickness of 30 nm by injecting Ar:N₂:CH₄=5 sccm:5 sccm:0.8 sccm as a process gas and using a process power of 1.0 kW. The third layer was formed of a CrCON film having a thickness of 9 nm by injecting Ar:N₂:CO₂=3 sccm:5 sccm:7.5 sccm as a process gas and using a process power of 1.4 kW.

As a result of measuring a sheet resistance of the conductive layer using a 4-point probe, a sheet resistance value was shown as 15.6 Ω/□, and when a surface roughness was measured by atomic force microscope (AFM), a surface roughness value was shown as 0.26 nm RMS. When the flatness of the backside of the substrate was measured with a flatness measuring instrument, the value of the flatness was shown as 180 mn and the stress was compressive stress. Therefore, it was confirmed that there is no problem in bonding with the electronic-chuck and there is no problem in using the conductive layer of Example 1 as the conductive layer.

A 40-layer reflection film was formed by alternately stacking Mo and Si layers on the front side of the substrate on which the conductive layer was formed, The reflection film was formed by alternately forming Mo and Si layers in an Ar gas atmosphere after mounting Mo and Si targets on ion beam deposition-low defect density (IBD-LLD) equipment. In detail, the reflection film was formed by forming the Mo layer to a thickness of 2.8 nm, followed by forming the Si layer to a thickness of 4.2 nm, and repeatedly forming the Si layer and the Mo layer 40 cycles based on the Mo layer and the Si layer as one cycle. An uppermost layer of the reflection film was formed of the Si layer to suppress surface oxidation.

As a result of measuring the reflectance of the reflection film at 13.5 nm using reflectometer equipment, the reflectance was 67.7%, and as a result of measuring the surface roughness using the AFM equipment, the surface roughness was 0.125 nm Ra.

A capping film that has a thickness of 2.5 nm and is made of RuN was formed on the reflection film in a nitrogen atmosphere by using the IBD-LDD equipment and using a Ru target. As a result of measuring the reflectance in the same manner as the reflection film after the formation of the capping film, it was confirmed that the reflectance is 66.8% at a wavelength of 13.5 nm, and therefore, there is almost no loss of reflectance.

An absorbing film was formed on the capping film using the DC magnetron sputtering equipment. In detail, the absorbing film formed of a Ta film having a thickness of 50 nm was formed on the capping film by using the Ta target. Ar=8 sccm as a process gas and using a process power of 0.7 kW. The absorbing film showed a reflectance of 2.2% with respect to a wavelength of 13.5 nm.

The flatness of the front side of the substrate was 178 nm when measured using a flatness meter, and therefore it was confirmed that the flatness was the desired value or less.

The manufacture of the blankmask for EUV was completed by spin coating on the absorbing film to form a 100 nm-thick resist film 109.

### EXAMPLE 2

In Example 2, a composition of a second layer of a conductive layer was changed from CrCN to CrN. In order to form the second layer, a CrN film having a thickness of 32 nm was formed by injecting Ar:N₂=5 sccm:5 sccm as a process gas and using a process power of 1.0 kW. Other processes are the same as in Example 1. As a result of measuring a sheet resistance of the conductive layer using a 4-point probe, a sheet resistance value was shown as 20.2 Ω/□, and when a surface roughness was measured by atomic force microscope (AFM), a surface roughness value was shown as 0.28 nm RMS. Therefore, it was confirmed that there is no problem in bonding with the electronic-chuck and there is no problem in using the conductive layer of Example 2 as the conductive layer.

When the flatness of the conductive layer was measured with a flatness meter, the value of 190 nm was obtained, and the stress was compressive stress. The flatness of the front side of the substrate after the process of forming the absorbing film was completed was 216 nm when measured using the flatness meter, and therefore, it was confirmed that the flatness was the desired value or less.

### EXAMPLE 3

In Example 3, a composition of a first layer was changed from CrCON to CrCO. In order to form the first layer, a CrCO film having a thickness of 39 nm was formed by injecting Ar:CO₂=6 sccm:6 sccm as a process gas and using a process power of 1.4 kW Other processes are the same as in Example 1. As a result of measuring a sheet resistance of a conductive layer using a 4-point probe, a sheet resistance value of 21.6 Ω/□ was shown, and when a surface roughness was measured by atomic force microscope (AFM), a surface roughness value of 0.27 nm RMS was shown. Therefore, it was confirmed that there is no problem in bonding with the electronic-chuck and there is no problem in using the conductive layer of Example 3 as the conductive layer.

When the flatness of the conductive layer was measured with a flatness meter, the value of 190 nm was obtained, and the stress was compressive stress. The flatness of the front side of the substrate after the process of forming the absorbing film was completed was 203 nm when measured using the flatness meter, and therefore, it was confirmed that the flatness was less than the desired value.

### Comparative Example 1

In Comparative Example 1, a conductive layer was formed of a single layer of CrN. In order to form the conductive layer, a CrN film having a thickness of 60 nm was formed by injecting a process gas of Ar:N₂=5 sccm:5 sccm and a process power of 1.0 kW. As a result of measuring a sheet resistance of the conductive layer using a 4-point probe, a sheet resistance value was shown as 20.1 Ω/□, and when a surface roughness was measured by atomic force microscope (AFM), a surface roughness value was shown as 0.2 nm RMS. Therefore, it was confirmed that there is no problem in bonding with the electronic-chuck and there is no problem in using the conductive layer of Comparative Example 1 as the conductive layer.

When the flatness of the conductive layer was measured with a flatness meter, the value of 240 nm was obtained, and the stress was tensile stress. The flatness of the front side of the substrate after the process of forming the absorbing film was completed was 715 nm when measured using the flatness meter, and therefore, it was confirmed that the flatness was more than the desired value.

Hereinabove, the disclosure has been specifically described through the structure of the disclosure with reference to the accompanying drawings, but this structure is only used for the purpose of illustrating and explaining the disclosure, and is not used to limit the meaning or the scope of the disclosure described in the claims. Therefore, those having ordinary skill in the technical field of the disclosure can understand that various modifications and equivalent other structures are possible from the structure. Accordingly, an actual technical scope of the disclosure is to be defined by the spirit of the appended claims.

What is claimed is:

1. A blankmask, comprising:
a substrate; and
a conductive layer that is attached to a backside of the substrate.
wherein the conductive layer includes a first layer, a second layer, and a third layer that are sequentially stacked on the backside of the substrate,
the first layer and the third layer are made of a material that contains chromium (Cr) and oxygen (O), and
the second layer is made of a material that does not contain the oxygen (O) but contains the chromium (Cr).

2. The blankmask of claim 1, wherein at least one of the first layer, the second layer, and the third layer is made of a material that further contains nitrogen (N).

3. The blankmask of claim 1, wherein at least one of the first layer, the second layer, and the third layer is made of a material that further contains carbon (C).

4. The blankmask of claim 1, wherein the first layer and the third layer are made of CrCON, and the second layer is made of CrCN.

5. The blankmask of claim 1, wherein the first layer is made of 20 to 70 at % of chromium (Cr), 30 to 80 at % of oxygen (O), and 0 to 50% of a sum total of nitrogen and carbon,
the second layer is made of 40 to 100% of chromium (Cr) and 0 to 60% of a sum total of nitrogen and carbon, and
the third layer is made of 20 to 70 at % of chromium (Cr), 30 to 80 at % of oxygen (O), and 0 to 50% of a sum total of nitrogen and carbon.

6. The blankmask of claim 1, wherein at least one of the first layer, the second layer, and the third layer is made of a material that further contains at least one element selected from the group consisting of hydrogen (H), boron (B), aluminum (Al), silver (Ag), cobalt (Co), copper (Cu), iron (Fe), hafnium (Hf), indium (In), molybdenum (Mo), nickel (Ni), niobium (Nb), silicon (Si), tantalum (Ta), titanium (Ti), zinc (Zn), and zirconium (Zr).

7. The blankmask of claim 6, wherein a content of the element is 15 at % or less.

8. The blankmask of claim 1, wherein the first layer has a surface roughness of 0.5 nm RMS or less.

9. The blankmask of claim 1, wherein the first layer has a thickness of 10 to 100 nm.

10. The blankmask of claim 1, wherein the second layer has a sheet resistance of 100 Ω/□ or less.

11. The blankmask of claim 1, wherein the second layer has a thickness of 10 to 60 nm.

12. The blankmask of claim 1, wherein the third layer has a surface roughness of 0.5 nm RMS or less.

13. The blankmask of claim 1, wherein the third layer has a thickness of 1 to 30 nm.

14. A photomask manufactured with the blankmask of claim 1.
